(19) United States
(12) Patent Application Publication
(10) Pub. No.: US 2013/0218495 A1
(43) Pub. Date: Aug. 22, 2013

(54) Method, Sensor Apparatus and System for Determining Losses in an Electrical Power Grid

(71) Applicants: David Benjamin Boone, Chilliwack (CA); Mischa Steiner-Jovic, Kelowna (CA)

(72) Inventors: David Benjamin Boone, Chilliwack (CA); Mischa Steiner-Jovic, Kelowna (CA)

(21) Appl. No.: 13/704,846

(22) PCT Filed: Jun. 17, 2011
(86) PCT No.: PCT/CA2011/000721

§ 371 Date: May 6, 2013

Related U.S. Application Data
(60) Provisional application No. 61/355,892, filed on Jun. 17, 2010.

(51) Int. Cl. G06Q 50/06; G01R 21/133

(52) U.S. Cl. CPC G06Q 50/06; G01R 21/133
USPC 702/62

(57) ABSTRACT

A field deployable sensor node for determining electrical usage in an electrical power grid comprises a sensor capable of removable engagement with a supply line electrical wire and capable of measurement of at least one of current and voltage to produce measurement data; an analog to digital conversion means; a microcontroller circuit; a transceiver; storage memory for data; and a means to communicate with other nodes and self-form into a communications network selected from the group consisting of a mesh, star, and tree network topology forming a Field Area Network (FAN).

### FIELD OF THE INVENTION

The present invention to the field of power monitoring and devices to achieve such means within a power grid.

### BACKGROUND OF THE INVENTION

Once electrical power leaves the distribution stations of electrical power utilities, billed usage is assumed to be equal to distributed usage. Often, this is not the case. Thus there is a need for a system that can be placed through the electrical grid network to determine where these loss events are occurring.

The magnitude of the problem is huge. It has been found that even in highly developed countries, approximately 10% of all electricity generated is lost within the electricity networks themselves. This figure rises to almost 25% (up to 35% in India) in less developed nations. One of the main reasons for this loss of power is the electricity provider's lack of knowledge of the electricity flowing in their medium voltage networks. Faults can go undetected for long periods of time and once detected are often difficult to locate over an expansive medium voltage network. It would be desirable to increase the provider's knowledge of the electrical properties in their medium voltage networks by closely monitoring the networks. This way, electricity providers can significantly reduce the amount of electricity lost in such networks and make considerable savings in the cost of generating the electricity. Furthermore, by closely monitoring their networks, electricity providers will be in a better position to correct faults in their networks quickly with a minimum of inconvenience to their customers, thereby providing an improved quality of efficient supply.

Previously, several attempts have been made to provide a monitoring device that will enable the electricity provider to closely monitor their medium voltage networks in a simple and cost effective manner. Two different types of monitoring devices are known: a) pole mounted devices and b) line mounted devices. As a general rule, a pole mounted device is mounted on the pole supporting the electricity lines at a fixed distance from the lines that it is charged to monitor. These devices are not the most commercially practical as they are difficult to install. A key factor in the accuracy of the calculation of the electrical properties, when using off line or pole mounted sensors, is the geometry of the sensor device in relation to the line that it is attempting to measure. In this instance, geometry means the spatial distance between the conductors, and the distance from the line arrangement to the sensor. This geometry information is difficult to obtain, time consuming, costly, and once the geometry is set, is subject to changes from environmental conditions, i.e. temperature of the line, sag, wind movement and subsidence of the poles whereon the device is mounted.

Line mounted devices are mounted directly onto the electrical line that is desired to be measured. Although more difficult and expensive to install these allow for more accurate measurements of the electrical properties to be taken and more detailed monitoring of the line to be carried out. They are not, however, without their problems. By having a single device, the calculations on the line that may be carried out are limited. Therefore, the required level of information cannot be obtained by using the known types of monitoring devices.

As line mounted devices are mounted directly onto the electrical line that must be measured (allowing for allow for more accurate measurements of the electrical properties to be taken and more detailed monitoring of the line to be carried out), they are more difficult and expensive to install. There are, however, problems associated with known types of line mounted monitoring devices. By having a single device, the calculations on the line that may be carried out are limited. Real time line loading information as well as reactive current information cannot be obtained from the single sensor. Therefore, the required level of information cannot be obtained by using the known types of monitoring devices.

One such known system discloses the use of a meter with high resolution being attached to the primary line, with the measured data to be compared to known consumption patterns, to detect atypical usage patterns or loss.

One problem with this known system is that it requires previous knowledge, or historical data to be known, or readily available in order to accurately detect losses. Furthermore, once an atypical measurement is detected, pin-pointing the loss or troubled area still requires a field operator to manually measure the heat signature of the transformer using infrared or laser technology not part of the system and not the actual consumption of the household or location in question.

It is an object of the present invention to obviate or mitigate the above disadvantages.

### SUMMARY OF THE INVENTION

The present invention provides, in one embodiment, a field deployable sensor node for determining electrical usage in an electrical power grid which comprises a sensor capable of removable engagement with a supply line electrical wire and capable of measurement of at least one of current and voltage to produce measurement data; an analog to digital conversion means; a microcontroller circuit; a transceiver; storage memory for data; and a means to communicate with other nodes and self-form into a communications network selected from the group consisting of a mesh, star, and tree network topology forming a Field Area Network (FAN).

The present invention provides, in another embodiment, a system of determining electrical usage in an electrical power grid which comprises two or more sensor and preferably more than three nodes for determining electrical usage in an electrical power grid, wherein each sensor node comprises: a) a sensor capable of removable engagement with a supply line electrical wire and capable of measurement of at least one of current and voltage to produce measurement data; b) an analog to digital conversion means; c) a microcontroller circuit; d) a transceiver; e) storage memory for data; and f) a means to communicate with other nodes such that each sensor node is capable of communication with its neighbour sensor nodes and self-forming into a communications network selected from the group consisting of a mesh, star, and tree network topology forming a Field Area Network (FAN).

The present invention provides, in another embodiment, a method for determining electrical usage in an electrical power grid which comprises providing a sensor node in removable engagement with a supply line electrical wire, such sensor measuring at least one of current and voltage to produce measurement data; monitoring the supply line electrical wire and measuring and collecting said data within said sensor node; transmitting data between said sensor node and at least one adjacent sensor node, said sensor node and the adjacent sensor node self-forming into a communications network selected from the group consisting of a mesh, star, and tree network topology forming a Field Area Network (FAN); transmitting data to at least one network manager for aggregation; and analyzing said measurement data.

The device, method and system of the present invention afford many advantages. In essence, what is provided is a suite of wireless smart sensors that can be quickly yet removably deployed within a distribution grid to help identify areas of electrical loss. Most importantly, the sensors communicate wirelessly with each other to “self-form” a network, which (“mesh network”) has previously never been achieved in this context before. The sensors of the present invention preferably communicate with backend analytics software within a network manager to assess and mitigate losses. The sensors of the present invention are completely mobile and are deployable with standard industry tools and without wire splicing in any way. As such, monitoring can be achieved without service disruption and without fixed infrastructure costs. In addition, such sensors can be deployed (and thereafter removed) quickly and efficiently without infringing on private property rights.

### DESCRIPTION OF THE FIGURES

The following figures set forth embodiments in which like reference numerals denote like parts. Embodiments are illustrated by way of example and not by way of limitation in all of the accompanying figures.

FIG. 1 is a system diagram view of an example of the implementation of a deterministic electrical power loss detection system according to an embodiment;

FIG. 2 is a block diagram of the measurement node;

FIG. 3 is a block diagram of the network management unit;

FIG. 4 is a process flow diagram of deploying a measurement device in the field;

FIG. 5 is a flowchart diagram of the peer-to-peer association of one measurement node to another;

FIG. 6 is a perspective view of a sensor node in accordance with one aspect of the present invention;

FIG. 7 is a side view of a sensor node in accordance with one aspect of the present invention;

FIG. 8 is a cross-sectional view through a-a of FIGS. 7; and

FIG. 9 illustrates a grid system showing a plurality of sensor nodes and network managers of the present invention in situ.

### PREFERRED EMBODIMENTS OF THE INVENTION

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

With the scope of the present invention, the “power factor” of an AC electric power system is defined as the ratio of the real power flowing to the load to the apparent power in the circuit, and is a dimensionless number between 0 and 1 (frequently expressed as a percentage, e.g. 0.5 pf=50% pf). Real power is the capacity of the circuit for performing work in a particular time. Apparent power is the product of the current and voltage of the circuit. Due to energy stored in the load and returned to the source, or due to a non-linear load that distorts the wave shape of the current drawn from the source, the apparent power will be greater than the real power. In other words, the power factor is the ratio between real power and apparent power in a circuit. It is a practical measure of the efficiency of a power distribution system. For two systems transmitting the same amount of real power, the system with the lower power factor will have higher circulating currents due to energy that returns to the source from energy storage in the load. These higher currents produce higher losses and reduce overall transmission efficiency. A lower power factor circuit will have a higher apparent power and higher losses for the same amount of real power.

The power factor is one when the voltage and current are in phase. It is zero when the current leads or lags the voltage by 90 degrees. Power factors are usually stated as “leading” or “lagging” to show the sign of the phase angle, where leading indicates a negative sign.

With the scope of the present invention, “harmonics” are defined as, “integral multiples of the fundamental frequency. AC power is delivered throughout the distribution system at a fundamental frequency of 60 Hz. (50 Hz in Europe.) As such, the 3rd harmonic frequency is 180 Hz, the 5th is 300 Hz, etc. In the US, the standard distribution system in commercial facilities is 208/120 wye. There are three phase wires and a neutral wire. The voltage between any two phase wires is 208, and the voltage between any single phase wire and the neutral wire is 120. All 120 volt loads are connected between a phase and neutral. When the loads on all three phases are balanced (the same fundamental current is flowing in each phase) the fundamental currents in the neutral cancel and the neutral wire carries no current. When computer loads and other loads using switched mode power supplies are connected, however, the situation changes.

Like the fundamental current, most harmonic currents cancel out on the neutral wire. However, the 3rd harmonic current, instead of canceling, is additive in the neutral. Thus if each phase wire were carrying, in addition to fundamental current, 100 amps of 3rd harmonic current, the neutral wire could be carrying 300 amps of 3rd harmonic current. In many cases, neutral-wire current can exceed phase wire currents. This extra current provides no useful power to the loads. It simply reduces the capacity of the system to power more loads, and produces waste heat in all the wiring and switchgear. When the 3rd harmonic current returns to the transformer it is reflected into the transformer primary where it circulates in the delta winding until it is dissipated as heat. The result is overheated neutral wires, switchgear, and transformers. This can lead to failure of some part of the distribution system and, in the worst case, fires. In addition, waste heat in all parts of the system increases energy losses and results in higher electrical bills. It is estimated that 3rd harmonic currents can increase electrical costs by as much as 8%.

Switch mode power supplies draw current in spikes, which requires the AC supply to provide harmonic currents. The largest harmonic current generated by the SMPS is the 3rd. The magnitude of this harmonic current can be as large as or larger than the fundamental current. Also generated, in smaller amounts, are the 5th, 7th, and all other odd harmonic currents.

With the scope of the present invention, “transients” are defined, whether currents or voltages, as occurrences which are created fleetingly in response to a stimulus or change in the equilibrium of a circuit. Transients frequently occur when power is applied to or removed from a circuit, because of expanding or collapsing magnetic fields in inductors or the charging or discharging of capacitors.

With the scope of the present invention, “phase angle or phase or current (p”, is the angle of difference (in degrees) between voltage and current; Current lagging Voltage (Quadrant I Vector), Current leading voltage (Quadrant IV Vector).

Within the scope of the present invention, the tem “mesh networking” refers to Mesh networking (topology) which is a type of networking wherein each node must not only capture and disseminate its own data, but also serve as a relay for other sensor nodes, that is, it must collaborate to propagate the data in the network.

A mesh network can be designed using a flooding technique or a routing technique. When using a routing technique, the message propagates along a path, by hopping from node to node until the destination is reached. To ensure all its paths' availability, a routing network must allow for continuous connections and reconfiguration around broken or blocked paths, using self-healing algorithms.

The present disclosure relates to the identification of power losses in an electrical grid. In particular, the identification of power losses using a deterministic method wherein data is collected from measurement nodes placed within the electrical grid that measure electrical usage directly on an electrical power line and communicate this usage data via a wireless network. This allows utility companies to detect losses within their electrical power grid using smart measurement devices with wireless capabilities. These measurement devices, or measurement nodes, are placed on the electrical utility wire to store and transmit the measured flow of electrical power.

A plurality of power measurement devices, which utilize AC load current transducers as the main method of current measurement through the electrical wire, measure and monitor power usage. In one embodiment, the power measurement devices monitor power theft and system losses.

One embodiment of the present invention provides a field deployable sensor node for determining electrical usage in an electrical power grid which comprises a sensor capable of removable engagement with a supply line electrical wire and capable of measurement of at least one of current and voltage to produce measurement data; an analog to digital conversion means; a microcontroller circuit; a transceiver; storage memory for data; and a means to communicate with other nodes and self-form into a communications network selected from the group consisting of a mesh, star, and tree network topology forming a Field Area Network (FAN).

In one aspect, the sensor node is in direct contact with the supply line electrical wire. In another aspect, the sensor node is in communication with but not direct contact with the supply line electrical wire. In one aspect, the sensor node is capable of taking measurements over selected time intervals. In one aspect, the sensor node is capable of removable engagement with a supply line electrical wire and capable of measurement of at least one of current and voltage to produce measurement data. In one aspect, the sensor is a transformer clamped around the supply line electrical wire which employs non-contact electromagnetic coupling to measure the at least one of current, voltage, phase angle, power factor, harmonics, and transients. In one aspect, the supply line electrical wire is one which is selected from the group consisting of a primary supply line (extending from pull box to transformer) and a secondary supply line (direct to residence or business). In one aspect, the sensor node is able, via the communications network, to transmit data to its neighbouring sensor nodes and wherein said sensor nodes are further able to communicate with one or more network managers.

Another embodiment of the invention provides a system of determining electrical usage in an electrical power grid which comprises two or more sensor nodes for determining electrical usage in an electrical power grid, wherein each sensor node comprises: a) a sensor capable of removable engagement with a supply line electrical wire and capable of measurement of at least one of current and voltage to produce measurement data; b) an analog to digital conversion means; c) a microcontroller circuit; d) a transceiver; e) storage memory for data; and f) a means to communicate with other nodes such that each sensor node is capable of communication with its neighbour sensor nodes and self-forming into a communications network selected from the group consisting of a mesh, star, and tree network topology forming a Field Area Network (FAN).

In one aspect, the system additionally comprises one or more network managers. Preferably, these one or more network managers which each comprise a modem capable of transmitting measurement data over a network. In one aspect, the system additionally comprises one or more network managers which relay data from the sensor nodes to a server via a means selected from the group consisting of cellular, satellite, WiMAX and Wifi. In one aspect, the system additionally comprises one or more network managers which aggregate and relay the data from the sensor nodes to a server and wherein said server enables viewing of the data by a viewer via an interface. In one aspect, the system additionally comprises one or more network managers which aggregate and relay the data from the sensor nodes to a server and wherein said server enables viewing of the data by a viewer via an interface and wherein said interface is selected from the group consisting of a desktop computer, a laptop computer, a hand-held microprocessing device, a tablet, a Smartphone, iPhone®, iPad®, PlayBook® and an Android® device. Those skilled in the relevant art will appreciate that the invention can be practiced with any computer configurations, including hand-held devices, multiprocessor systems, microprocessor-based or programmable consumer electronics, personal computers (“PCs”), network PCs, mini-computers, mainframe computers, and the like. In one aspect, the measurement data is communicated wirelessly on a peer-to-peer network to a central network manager. In one aspect, the measurement data is collected in situ from the sensor nodes or network managers. This can be achieved by workers on site either on the ground or using a bucket truck. In one aspect, the system comprises more than three sensor nodes. In one aspect, the system may be temporarily field deployable on one or more supply line electrical wires and then moved and reset on other supply line electrical wires without the requirement of any wire splicing for such deployment and re-deployment.

The present invention provides, in yet another embodiment, a method for determining electrical usage in an electrical power grid which comprises providing a sensor node in removable engagement with a supply line electrical wire, such sensor measuring at least one of current and voltage to produce measurement data; monitoring the supply line electrical wire and measuring and collecting said data within said sensor node; transmitting data between said sensor node and at least one adjacent sensor node, said sensor node and the adjacent sensor node self-forming into a communications network selected from the group consisting of a mesh, star, and tree network topology forming a Field Area Network (FAN); transmitting data to at least one network manager for aggregation; and analyzing said measurement data.

In one aspect, the method additionally employs one or more network managers. In one aspect, the method additionally employs one or more network managers which each comprise a modem which transmits measurement data over a network. In one aspect, the method additionally employs one or more network managers which relay data from the sensor nodes to a server via a means selected from the group consisting of cellular, satellite, WiMAX and Wifi. In one aspect, the method additionally employs one or more network managers which aggregate and relay the data from the sensor nodes to a server and wherein said server enables viewing of the data by a viewer via an interface. In one aspect, the method additionally employs one or more network managers which aggregate and relay the data from the sensor nodes to a server and wherein said server enables viewing of the data by a viewer via an interface and wherein said interface is selected from the group consisting of a desktop computer, a laptop computer, a hand-held microprocessing device, a tablet, a Smartphone, iPhone®, iPad®, PlayBook® and an Android® device. Those skilled in the relevant art will appreciate that the invention can be practiced with any computer configurations, including hand-held devices, multiprocessor systems, microprocessor-based or programmable consumer electronics, personal computers (“PCs”), network PCs, mini-computers, mainframe computers, and the like. In one aspect, measurement data is communicated wirelessly on a peer-to-peer network to a central network manager. In yet another aspect, the measurement data is collected in situ from the sensor nodes or network managers. This may be achieved by workers on site either on the ground or using, for example, a bucket truck. In yet another aspect, the method uses more than three sensor nodes. In another aspect, the sensors for use in the method may be temporarily field deployable on one or more supply line electrical wires and then moved and reset on other supply line electrical wires without the requirement of any wire splicing for such deployment and re-deployment. In yet another aspect, the measurement data is transmitted wirelessly to a server; and an analysis is made to determine if a loss has occurred. In another aspect, the supply line electrical wire is a medium voltage line.

In a most preferred form, the field deployable node includes one or more components including, but not limited to, a clamp-on current sensor, a micro controller and an RF module. The nodes communicate with each other to self-form into a mesh, star, or tree network topology forming a Field Area Network (FAN). The power usage information from each device is then relayed through said network, and sent to the utility to be compared to other usage data. The system is field deployable requiring no splicing into the electrical wire to allow for quick setup and extraction of the system to allow movement of said system to another location.

In one embodiment, a deterministic loss detection system in which a plurality of measurement nodes with current and voltage measuring capabilities is placed directly on the electrical wire to accurately measure the current flow, and power usage, of a facility, building, or home that the electrical power wire is servicing. Measurement nodes have the capability of communicating wireless on a peer-to-peer based medium range wireless network, and data is transmitted, or hopped, back to a central network manager that then sends data to a database via a cellular, satellite, WiMAX, or WiFi network. Data is then post processed for suspicious losses that may be occurring on the lines the measurement nodes are placed, and analysis is sent to a user where they may generate reports, or view trending data in a client side computer application.

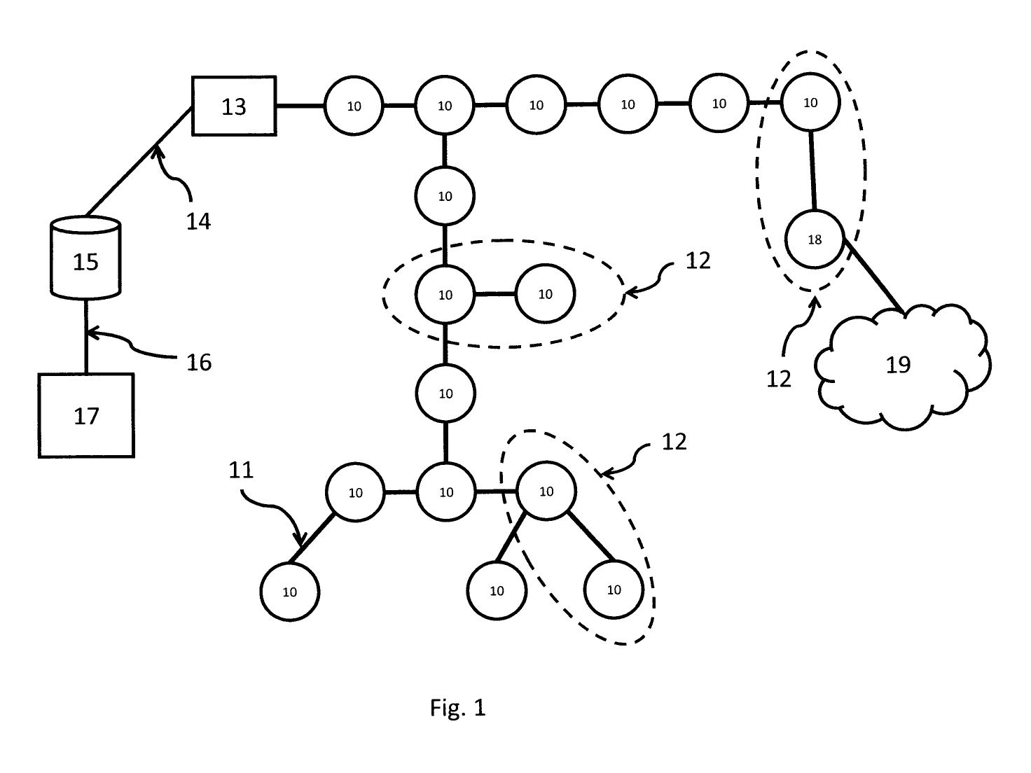

Referring now to FIG. 1, a plurality of reference measurement nodes 10 and one or more network managers 11 are generally shown. The measurement nodes 10 are coupled to the wires of the electrical power grid, which for above ground systems, is in a linear fashion as shown.

FIG. 1 represents an example network layout that may be encountered when measurement devices 10 are in the field of an electrical power grid. The network consists of nodes 10 communicating with adjacent nodes 10 to form what is referred to as a low power wireless area network. Network topologies for such networks include star, mesh, and tree layout. In the field of electrical utilities, a tree style network topology is typically experienced, and is shown as an example in FIG. 1. A network manager 13 can also be placed in the field to become part of the same network. However, the network does not require a network 13 manager to communicate, but may be used to route data to a database 15 for storage. All nodes 10 can communicate with any other node 10 within the network independent of the network manager 13 or surrounding nodes 10. Each node 10 will prefer to associate with its closest neighbor node 12 and communicate with this node, forming a local node communication link 11, such that data transmission will route towards the network manager 13. This type of peer-to-peer device communication association 12 ensures that any node 10 communicates with its closest neighbor resulting in efficient data transmission on the network. Also, any node 10 may communicate with a smart meter 18 and communicate directly to the smart meter 18. Also the smart meter 18 may communicate directly to node 10 that is in range of communication and either device may initiate communication with the other. Data collected by a node 10 may be relayed through a smart meter 18 Automatic Meter Reading (AMR) or Advanced Metering Infrastructure (AMI) communication network 19. If AMR/AMI communication network 19 is not available or not preferred, data is routed back to the network manager 13, data is transmitted via a cellular, WiFi, WiMAX, or suitable wired connection 14 such that the data is received by a server 15 for storage. A user accesses this data from a PC computer 17 over a secure connection 16 such that application software can display the results connected from measurement nodes 10.

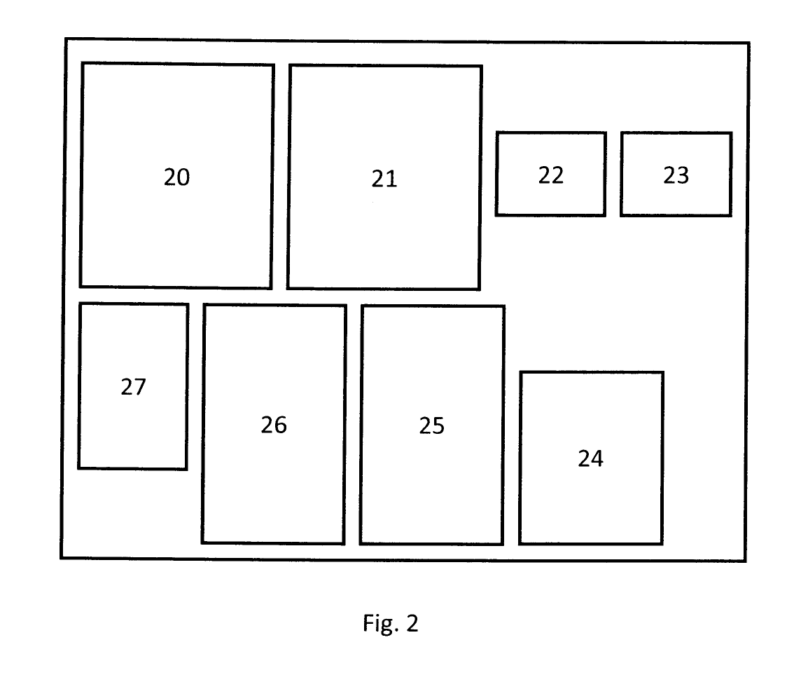

The measurement node 10 is shown in a block diagram in FIG. 2 consists of a current transformer 27 clamped around the electrical utility wire, and utilizes non-contact electromagnetic coupling to measure the current flow through the wire to make a measurement of the power flowing through the line. This makes the device able to measure power without the need to disrupt service to utility customers. The measurement node is also able to charge itself using inductive coupling via a battery charging circuit. The measurement node 10 also contains an analog to digital conversion circuit 20, a microcontroller 21, a transceiver 22, an antenna 23, memory 24 for data storage, a battery 25, and power control circuit 26.

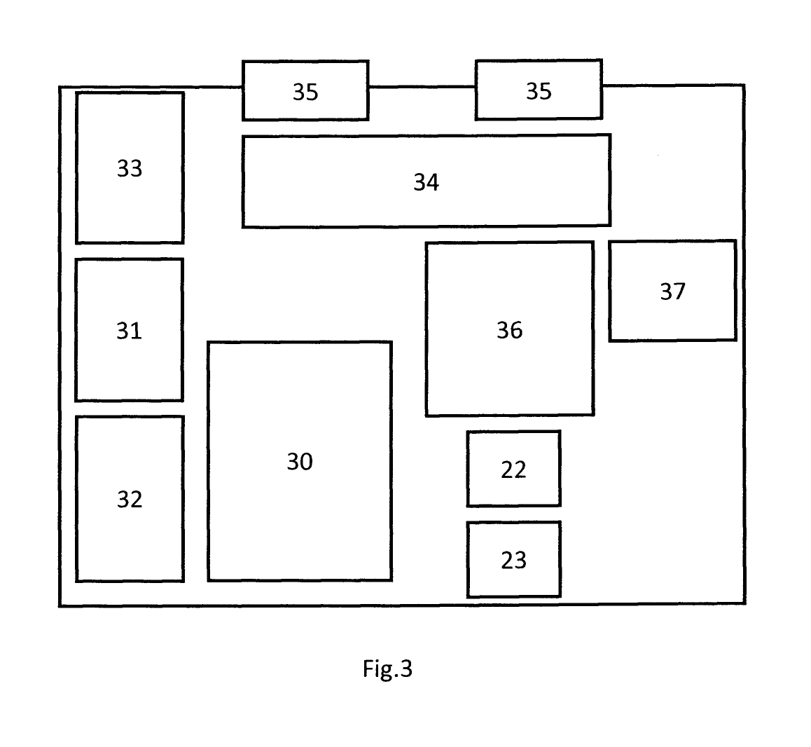

Furthermore, a network manager 13 of which a block diagram can be seen in FIG. 3 consists of a battery 30 which supplies power to the device through a power control circuit 33 that also may include an inductive charging circuit 32 coupled to an inductive charging module 31 allowing the network manager to remain in the field indefinitely. Furthermore, the device consists of a modem 34 supported by a MIMO antenna system 35 so that it may transmit data received from the network FIG. 1 over a cellular, WiMAX, Satellite, or WiFi link such that this data will be received by a central server 15 over a secure link 14. This data would become available to the user via a secure internet link 16 for viewing on a PC 17. The network manager is controlled by a microcontroller 36 with memory storage 37.

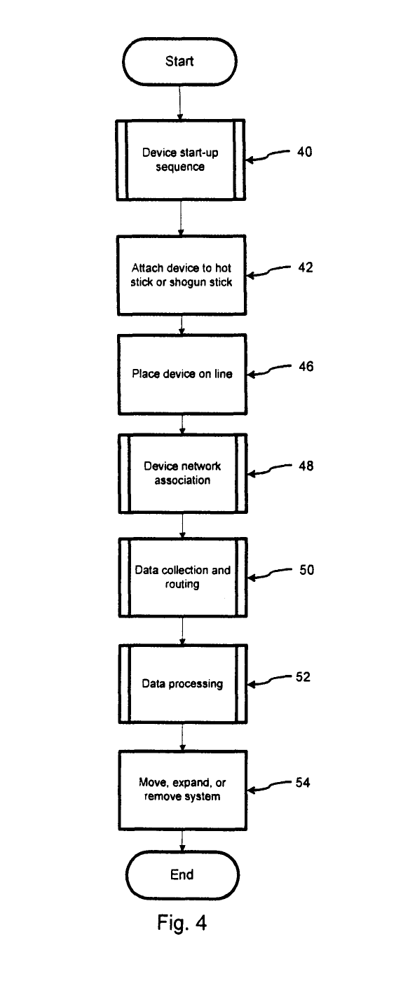

FIG. 4 describes the method of deploying the measurement nodes 10 in the field to achieve a network as shown in FIG. 1. The measurement node 10 will initially be turned on by the field worker, at this time the measurement node's 10 microcontroller 21 will turn on, using power from the on board battery 25 and proceed through a start-up sequence 40 whereby it becomes ready for measurement on a power line. A field worker will attach the measurement node 10 to an industry standard hot stick or shotgun stick, and place the measurement node 10 on the utility power line 46. The measurement node 10 will then begin to attempt a predefined network association process 48 where it will associate with adjacent or nearby measurement nodes to communicate and form a child-parent relationship 12. Once a node becomes part of the associated network data collection and routing 50 begins and measurement nodes 10 will begin to transfer measured data to the network manager 13 where it will be further sent to a database 15 for data processing 52. Lastly, the network can be expanded, moved to a new location in the field, or it can be removed from its current setting 54.

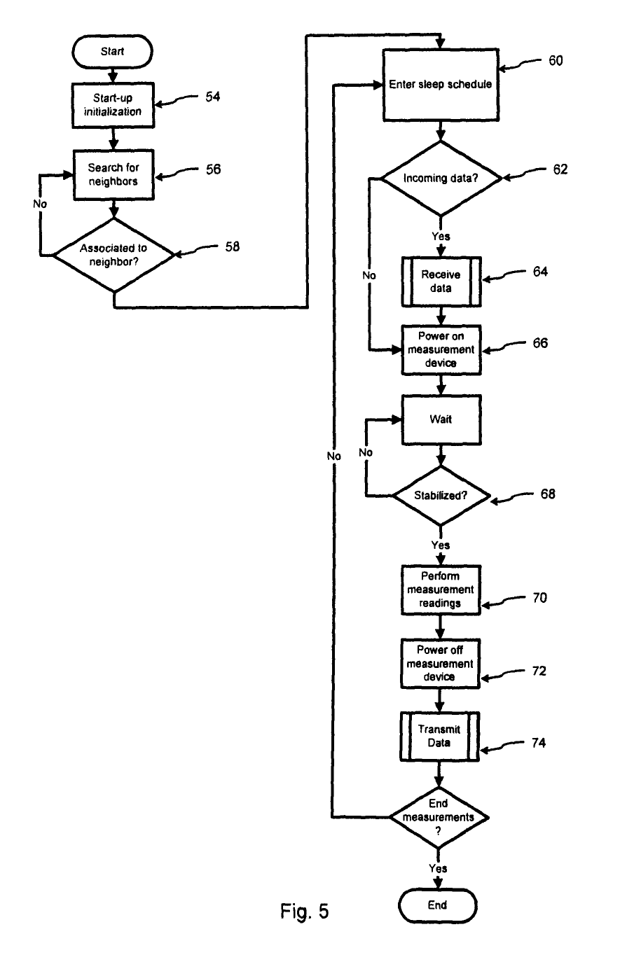

FIG. 5 shows in finer detail the start-up sequence 40 and device network association 48 indicated in FIG. 4. Start-up initialization 54 controls the boot-up and power on sequence of the measurement nodes on board microcontroller 21, transceiver 23, and current transformer measurement 27. The measurement node 10 will then search for neighbor devices 56 to form the child-parent relationship 12, and upon associating with a neighboring node 58 will enter a scheduled sleep routine 60. Based on this sleep and wake routine 60 the measurement node 10 will be capable and ready to receive incoming data 62 from neighboring nodes by turning on its transceiver 22 in receive mode and it will receive the data to either store in its own on board memory 24 or passing the data on to its parent node 12. To begin power measurement process, the node will power on the current transformer measurement device 66. Once the current transformer 27 is stabilized 68 the measurement node 10 will perform its scheduled measurement readings 70, and then power off the current transformer measurement 72 for battery 25 optimization. The data collected will then be passed to the network layer to be transmitted 74 via the microcontroller 21 to the transceiver 22 in transmit mode to the parent node via the local node communication link 11 along the network data path to the network manager 13.

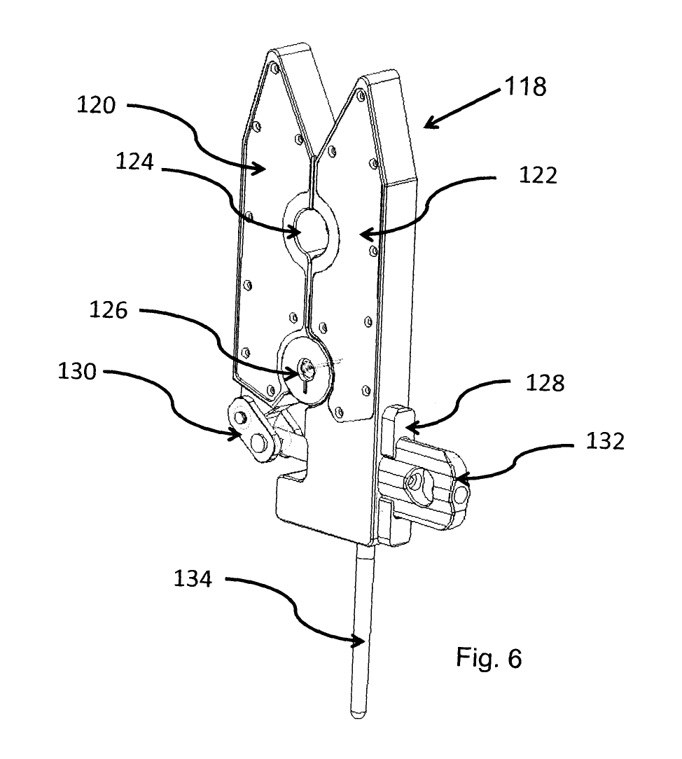

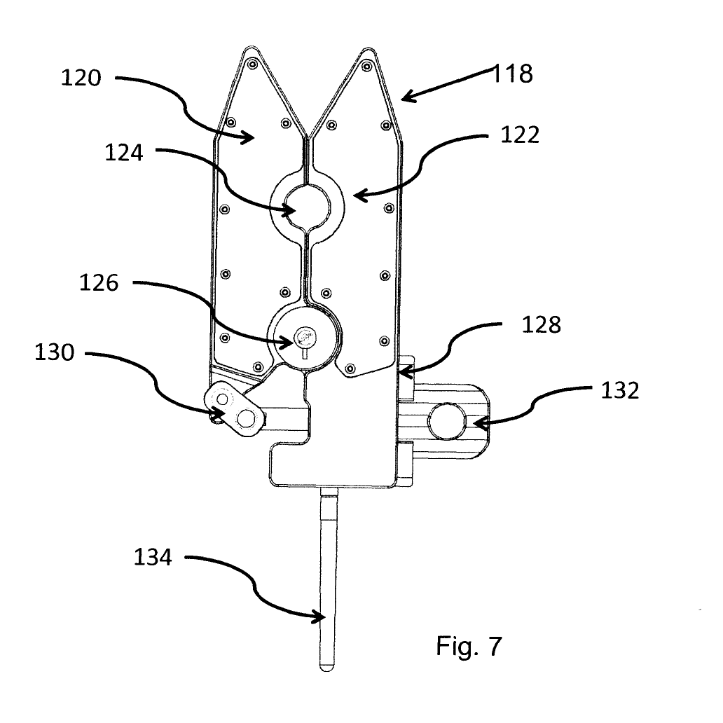

In a preferred embodiment, as shown in FIGS. 6-8, there is provided node 118 which is configured to be associated with a supply line electrical wire (not shown). Node 118 comprises left clamp arm 120 and right clamp arm 122 moveable between an open position for receiving a wire and a closed position for securely holding a wire via joint/pivot point 126. More particularly, joint 126 provides a means for left clamp arm 120 to open away from right clamp arm 122. Within the body of left clamp arm 120 is housed the measurement sensor node electronics and left side measurement sensor current transformer. Within the body of right clamp arm 122 is housed the sensor node electronics and right side measurement sensor current transformer. Opening 124 is defined between the abutting facing surfaces of left clamp arm 120 and right clamp arm 122 and provides a housing for a supply line electrical wire , when the sensor in operation, such housing providing contact between the sensor current transformers and the wire. Extruding portion 128 allows a Power Line Technician electrical worker to mate a shotgun stick (not shown) to node 118 such that key 132 can be used to pull the shaft through the main body of the node with actuation at hinge 130 to disengage left arm clamp 120 and “open” the node. As such, hinge 130 is for shotgun stick key actuation. Antenna 134 provides a means for transmitting data.

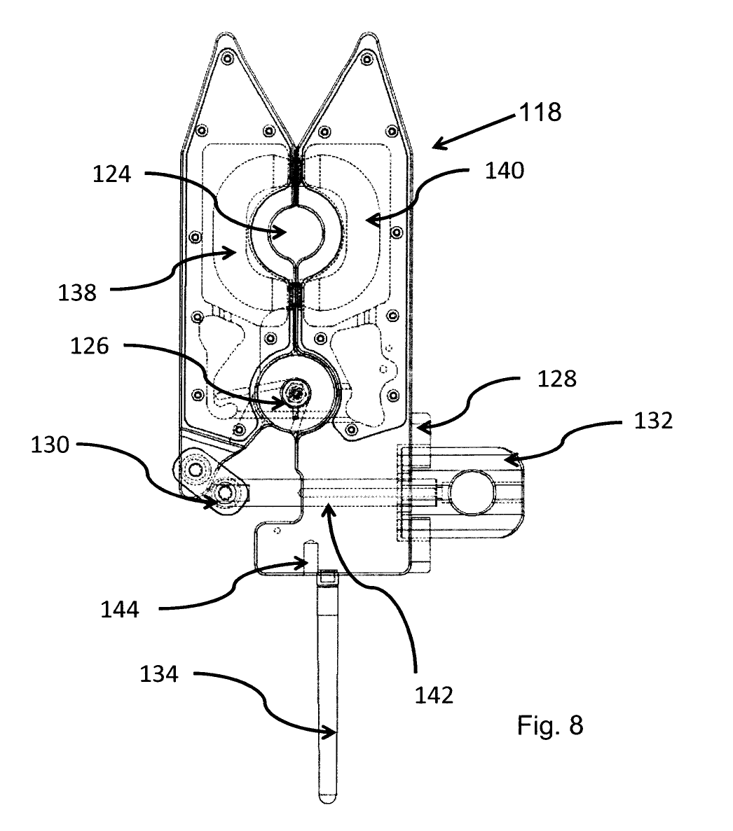

Turning specifically to FIG. 8, and with reference to the internal components of sensor node 118, there is provided at 138 a left side measurement sensor current transformer and at 140 a right side measurement sensor current transformer. Shaft 142 runs through the body of the node and allows a hole (within key 132) to actuate hinge 130 for the opening of node 118. Mounting hole 144 allows a Power Line Technician electrical worker to attach a rod (not shown) into the cavity of the body of the measurement node such that a telescoping pole may be used to deploy and remove the device from the ground, obviating, in some cases, the need for a bucket truck.

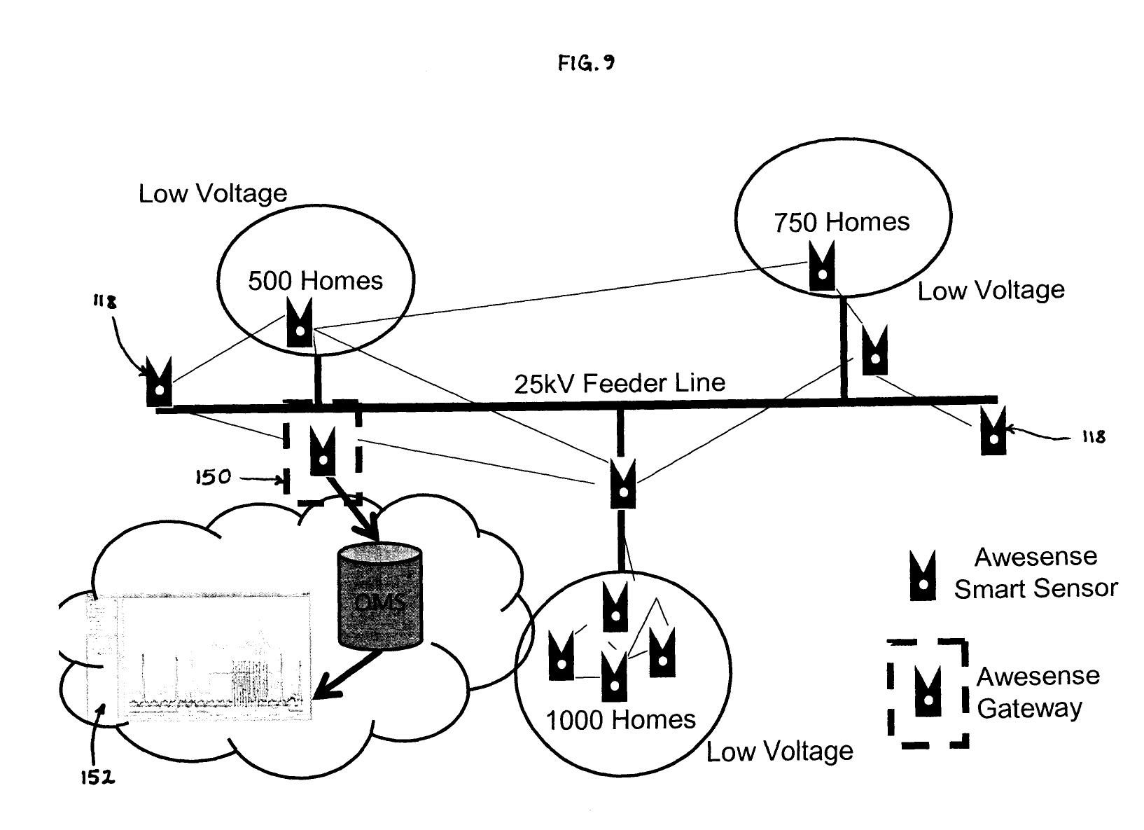

Turning to FIG. 9, there is provided a schematic of a power grid showing a plurality of sensor nodes 118 and network manager (Gateway) 150 of the present invention in situ, wherein nodes are provided at a series of step-down locations from 25 kV feeder line to homes within each sub-grid. Aggregated measurement data from network manager 150 is communicated to a server and such data collated for user interface display 152.

In a further embodiment of the invention, each measurement sensor has the means and ability to measure one or more of the instantaneous current (I_{c}), the peak current, (Iₚₖ), the root-mean square (RMS) current, (I_{RMS}), the harmonic content of the current, and the phase of the current in its associated medium voltage overhead line. By having the capability to measure one or more of these properties, further information relating to faults on the line may be derived by the system administrators. A comprehensive overview of the network may be obtained. Any of the measurable properties described herein may be selected to be measured over any desired time frame prior to removal of the sensor from a location.

Advantages of the method, system and node described herein for detecting losses in an electrical power grid include: enhanced versatility; ease in deployment and removal; ease in relocation, no requirement for knowledge of previous usage data or stored consumption data from the utility, very minimal field worker effort, easily expandable from as little as one sensor unit to many thousands, all of which can be mesh networked and it is easily adaptable to a variety of loss sources such as power theft (for example, grow operations etc.), antiquated or aging equipment, line losses, etc.

In a preferred form, the sensor nodes of the present invention are “self-healing”. More specifically, if one sensor ceases to operate, the entire mesh network comprising the plurality of sensors and optionally network managers will reorganize itself under its own determination to find the next best routing path for the data. This is done without input from a user. Such determination systems are embedded in the sensor microprocessor.

In operation, if the data acquired using the sensor nodes, system and/or method of the invention indicates possible power loss, flaws, abnormal consumption patterns, leakages or other problems, notification may be sent to a monitoring entity or to a utility. The sensors are easy to deploy electrical distribution line sensors, which, once clipped onto the line, self-form themselves into an IPv6 mesh network. The units instantly begin to relay measurement data back to central servers for post processing through the network manager (Gateway), which itself is also mobile like the measurement sensor nodes. The entire system can be expanded, contracted, and relocated at will which eliminates the need for fixed infrastructure as compared to other systems. Furthermore, the enterprise software provides managers and engineers in the office a real time dashboard with powerful analytics to help them consume large amounts of field measurement data in an effective manner.

Preferably, the sensor nodes communicate using open standards (using for example, IEEE802.15.4) as demanded by the utility industry. Each node within the system is capable of wirelessly hopping data from a sister node to the end of the router device. Sensor nodes can be placed in close proximity to one another or alternatively can be placed distances up to approximately one kilometer from one another.

New smart meter technology is rapidly being introduced to the industry to facilitate time-of-use metering at each residence, permitting utilities to charge for electrical usage dependent upon the time of use and for consumers to take advantage of times at which a lower cost is assessed to the use of electricity. The combination of smart metering at each residence and monitoring of power at an input line, using a system according to embodiments of the invention disclosed herein, provides significant improvement in the collection of data for reconciliation and identification of losses, including the detection of line loss such as through faulty overhead etc. Simply, the load provided at the primary line should be equal to the sum of all the consumptions measured at each residence, having consideration for known factors of line loss. A discrepancy signals a problem with some part of the line which can be located using the present invention or other means.

As such, in a most preferred form of the invention, there is a seamless two-way communications system between the sensor nodes and at least one electrical meter (smart meter). This includes communications with other smart grid devices (including but not limited to switches, relays, reclosers, breakers, transformers, regulators, and arresters, etc.).

Within the scope of the present invention, data acquisition may preferably be controlled by a computer or microprocessor. As such, the invention can be implemented in numerous ways, including as a process, an apparatus, a system, a computer readable medium such as a computer readable storage medium or a computer network wherein program instructions are sent over optical or communication links. In this specification, these implementations, or any other form that the invention may take, may be referred to as systems or techniques. A component such as a processor or a memory described as being configured to perform a task includes both a general component that is temporarily configured to perform the task at a given time or a specific component that is manufactured to perform the task. In general, the order of the steps of disclosed processes may be altered within the scope of the invention.

The following discussion provides a brief and general description of a suitable computing environment in which various embodiments of the system may be implemented. In particular, this is germane to the network managers, which aggregate measurement data and downstream to the servers which enables viewing of the data by a user at an interface.

Although not required, embodiments will be described in the general context of computer-executable instructions, such as program applications, modules, objects or macros being executed by a computer. Those skilled in the relevant art will appreciate that the invention can be practiced with other computer configurations, including hand-held devices, multiprocessor systems, microprocessor-based or programmable consumer electronics, personal computers (“PCs”), network PCs, mini-computers, mainframe computers, and the like. The embodiments can be practiced in distributed computing environments where tasks or modules are performed by remote processing devices, which are linked through a communications network. In a distributed computing environment, program modules may be located in both local and remote memory storage devices.

A computer system may be used as a server including one or more processing units, system memories, and system buses that couple various system components including system memory to a processing unit. Computers will at times be referred to in the singular herein, but this is not intended to limit the application to a single computing system since in typical embodiments, there will be more than one computing system or other device involved. Other computer systems may be employed, such as conventional and personal computers, where the size or scale of the system allows. The processing unit may be any logic processing unit, such as one or more central processing units (“CPUs”), digital signal processors (“DSPs”), application-specific integrated circuits (“ASICs”), etc. Unless described otherwise, the construction and operation of the various components are of conventional design. As a result, such components need not be described in further detail herein, as they will be understood by those skilled in the relevant art.

A computer system includes a bus, and can employ any known bus structures or architectures, including a memory bus with memory controller, a peripheral bus, and a local bus. The computer system memory may include read-only memory (“ROM”) and random access memory (“RAM”). A basic input/output system (“BIOS”), which can form part of the ROM, contains basic routines that help transfer information between elements within the computing system, such as during startup.

The computer system also includes non-volatile memory. The non-volatile memory may take a variety of forms, for example a hard disk drive for reading from and writing to a hard disk, and an optical disk drive and a magnetic disk drive for reading from and writing to removable optical disks and magnetic disks, respectively. The optical disk can be a CD-ROM, while the magnetic disk can be a magnetic floppy disk or diskette. The hard disk drive, optical disk drive and magnetic disk drive communicate with the processing unit via the system bus. The hard disk drive, optical disk drive and magnetic disk drive may include appropriate interfaces or controllers coupled between such drives and the system bus, as is known by those skilled in the relevant art. The drives, and their associated computer-readable media, provide non-volatile storage of computer readable instructions, data structures, program modules and other data for the computing system. Although a computing system may employ hard disks, optical disks and/or magnetic disks, those skilled in the relevant art will appreciate that other types of non-volatile computer-readable media that can store data accessible by a computer system may be employed, such a magnetic cassettes, flash memory cards, digital video disks (“DVD”), Bernoulli cartridges, RAMs, ROMs, smart cards, etc.

Various program modules or application programs and/or data can be stored in the computer memory. For example, the system memory may store an operating system, end user application interfaces, server applications, and one or more application program interfaces (“APIs”).

The computer system memory also includes one or more networking applications, for example a Web server application and/or Web client or browser application for permitting the computer to exchange data with sources via the Internet, corporate Intranets, or other networks as described below, as well as with other server applications on server computers such as those further discussed below. The networking application in the preferred embodiment is markup language based, such as hypertext markup language (“HTML”), extensible markup language (“XML”) or wireless markup language (“WML”), and operates with markup languages that use syntactically delimited characters added to the data of a document to represent the structure of the document. A number of Web server applications and Web client or browser applications are commercially available, such those available from Mozilla and Microsoft.

The operating system and various applications/modules and/or data can be stored on the hard disk of the hard disk drive, the optical disk of the optical disk drive and/or the magnetic disk of the magnetic disk drive.

A computer system can operate in a networked environment using logical connections to one or more client computers and/or one or more database systems, such as one or more remote computers or networks. A computer may be logically connected to one or more client computers and/or database systems under any known method of permitting computers to communicate, for example through a network such as a local area network (“LAN”) and/or a wide area network (“WAN”) including, for example, the Internet. Such networking environments are well known including wired and wireless enterprise-wide computer networks, intranets, extranets, and the Internet. Other embodiments include other types of communication networks such as telecommunications networks, cellular networks, paging networks, and other mobile networks. The information sent or received via the communications channel may, or may not be encrypted. When used in a LAN networking environment, a computer is connected to the LAN through an adapter or network interface card (communicatively linked to the system bus). When used in a WAN networking environment, a computer may include an interface and modem or other device, such as a network interface card, for establishing communications over the WAN/Internet.

In a networked environment, program modules, application programs, or data, or portions thereof, can be stored in a computer for provision to the networked computers. In one embodiment, the computer is communicatively linked through a network with TCP/IP middle layer network protocols; however, other similar network protocol layers are used in other embodiments, such as user datagram protocol (“UDP”). Those skilled in the relevant art will readily recognize that these network connections are only some examples of establishing communications links between computers, and other links may be used, including wireless links.

While in most instances a computer will operate automatically, where an end user application interface is provided, a user can enter commands and information into the computer through a user application interface including input devices, such as a keyboard, and a pointing device, such as a mouse. Other input devices can include a microphone, joystick, scanner, etc. These and other input devices are connected to the processing unit through the user application interface, such as a serial port interface that couples to the system bus, although other interfaces, such as a parallel port, a game port, or a wireless interface, or a universal serial bus (“USB”) can be used. A monitor or other display device is coupled to the bus via a video interface, such as a video adapter (not shown). The computer can include other output devices, such as speakers, printers, etc.

It is to be fully understood that the present methods, systems and devices also may be implemented as a computer program product that comprises a computer program mechanism embedded in a computer readable storage medium. For instance, the computer program product could contain program modules. These program modules may be stored on CD-ROM, DVD, magnetic disk storage product, flash media or any other computer readable data or program storage product. The software modules in the computer program product may also be distributed electronically, via the Internet or otherwise, by transmission of a data signal (in which the software modules are embedded) such as embodied in a carrier wave.

For instance, the foregoing detailed description has set forth various embodiments of the devices and/or processes via the use of examples. Insofar as such examples contain one or more functions and/or operations, it will be understood by those skilled in the art that each function and/or operation within such examples can be implemented, individually and/or collectively, by a wide range of hardware, software, firmware, or virtually any combination thereof. In one embodiment, the present subject matter may be implemented via ASICs. However, those skilled in the art will recognize that the embodiments disclosed herein, in whole or in part, can be equivalently implemented in standard integrated circuits, as one or more computer programs running on one or more computers (e.g., as one or more programs running on one or more computer systems), as one or more programs running on one or more controllers (e.g., microcontrollers) as one or more programs running on one or more processors (e.g., microprocessors), as firmware, or as virtually any combination thereof, and that designing the circuitry and/or writing the code for the software and or firmware would be well within the skill of one of ordinary skill in the art in light of this disclosure.

In addition, those skilled in the art will appreciate that the mechanisms taught herein are capable of being distributed as a program product in a variety of forms, and that an illustrative embodiment applies equally regardless of the particular type of signal bearing media used to actually carry out the distribution. Examples of signal bearing media include, but are not limited to, the following: recordable type media such as floppy disks, hard disk drives, CD ROMs, digital tape, flash drives and computer memory; and transmission type media such as digital and analog communication links using TDM or IP based communication links (e.g., packet links).

While the forms of node/apparatus, method and system described herein constitute preferred embodiments of this invention, it is to be understood that the invention is not limited to these precise forms. As will be apparent to those skilled in the art, the various embodiments described above can be combined to provide further embodiments. Aspects of the present systems, methods and nodes (including specific components thereof) can be modified, if necessary, to best employ the systems, methods, nodes and components and concepts of the invention. These aspects are considered fully within the scope of the invention as claimed. .For example, the various methods described above may omit some acts, include other acts, and/or execute acts in a different order than set out in the illustrated embodiments.

Further, in the methods taught herein, the various acts may be performed in a different order than that illustrated and described. Additionally, the methods can omit some acts, and/or employ additional acts.

These and other changes can be made to the present systems, methods and articles in light of the above description. In general, in the following claims, the terms used should not be construed to limit the invention to the specific embodiments disclosed in the specification and the claims, but should be construed to include all possible embodiments along with the full scope of equivalents to which such claims are entitled. Accordingly, the invention is not limited by the disclosure, but instead its scope is to be determined entirely by the following claims.

1. A field deployable sensor node for determining electrical usage in an electrical power grid comprises
a) a sensor capable of removable engagement with a supply line electrical wire and capable of measurement of at least one of current and voltage to produce measurement data;
b) an analog to digital conversion means;
c) a microcontroller circuit;
d) a transceiver;
e) storage memory for data; and
f) a means to communicate with other nodes and self-form into a communications network selected from the group consisting of a mesh, star, and tree network topology forming a Field Area Network (FAN).

2. The sensor node of claim 1 which is in direct contact with the supply line electrical wire.

3. The sensor node of claim 1 which is in communication but not direct contact with the supply line electrical wire.

4. The sensor node of claim 1 which is capable of taking measurements over selected time intervals.

5. The sensor node of claim 1 wherein the sensor is capable of removable engagement with a supply line electrical wire and capable of measurement of at least one of current and voltage to produce measurement data.

6. The sensor node of claim 1 wherein the sensor is a transformer clamped around the supply line electrical wire which employs non-contact electromagnetic coupling to measure the at least one of current, voltage, phase angle, power factor, harmonics, and transients.

7. The sensor node of claim 1 wherein the supply line electrical wire is one which is selected from the group consisting of a primary supply line and a secondary supply line.

8. The sensor node of claim 1, which is able, via the communications network, to transmit data to its neighbouring sensor nodes and wherein said sensor nodes are further able to communicate with one or more network managers.

9. A system of determining electrical usage in an electrical power grid which comprises two or more sensor nodes for determining electrical usage in an electrical power grid, wherein each sensor node comprises:
a) a sensor capable of removable engagement with a supply line electrical wire and capable of measurement of at least one of current and voltage to produce measurement data;
b) an analog to digital conversion means;
c) a microcontroller circuit;
d) a transceiver;
e) storage memory for data; and
f) a means to communicate with other nodes such that each sensor node is capable of communication with its neighbour sensor nodes and self-forming into a communications network selected from the group consisting of a mesh, star, and tree network topology forming a Field Area Network (FAN).

10. The system of claim 9 additionally comprising one or more network managers.

11. The system of claim 9 additionally comprising one or more network managers which each comprise a modem capable of transmitting measurement data over a network.

12. The system of claim 9 additionally comprising one or more network managers which relay data from the sensor nodes to a server via a means selected from the group consisting of cellular, satellite, WiMAX and Wifi.

13. The system of claim 9 additionally comprising one or more network managers which aggregate and relay the data from the sensor nodes to a server and wherein said server enables viewing of the data by a viewer via an interface.

14. The system of claim 9 additionally comprising one or more network managers which aggregate and relay the data from the sensor nodes to a server and wherein said server enables viewing of the data by a viewer via an interface and wherein said interface is selected from the group consisting of a desktop computer, a laptop computer, a hand-held microprocessing device, a tablet, a Smartphone, iPhone®, iPad®, PlayBook® and an Android® device.

15. The system of claim 9 wherein measurement data is communicated wirelessly on a peer-to-peer network to a central network manager.

16. The system of claim 10 wherein the measurement data is collected in situ from the sensor nodes or network managers.

17. The system of claim 9 comprising more than three sensor nodes.

18. The system of claim 9 which may be temporarily field deployable on one or more supply line electrical wires and then moved and reset on other supply line electrical wires without the requirement of any wire splicing for such deployment and re-deployment.

19. A method for determining electrical usage in an electrical power grid comprising:
providing a sensor node in removable engagement with a supply line electrical wire, such sensor measuring at least one of current and voltage to produce measurement data;
monitoring the supply line electrical wire and measuring and collecting said data within said sensor node;
transmitting data between said sensor node and at least one adjacent sensor node, said sensor node and the adjacent sensor node self-forming into a communications network selected from the group consisting of a mesh, star, and tree network topology forming a Field Area Network (FAN);
transmitting data to at least one network manager for aggregation; and
analyzing said measurement data.

20. The method of claim 19 additionally employing one or more network managers.

21. The method of claim 19 additionally employing one or more network managers which each comprise a modem which transmits measurement data over a network.

22. The method of claim 19 additionally employing one or more network managers which relay data from the sensor nodes to a server via a means selected from the group consisting of cellular, satellite, WiMAX and Wifi.

23. The method of claim 19 additionally employing one or more network managers which aggregate and relay the data from the sensor nodes to a server and wherein said server enables viewing of the data by a viewer via an interface.

24. The method of claim 19 additionally employing one or more network managers which aggregate and relay the data from the sensor nodes to a server and wherein said server enables viewing of the data by a viewer via an interface and wherein said interface is selected from the group consisting of a desktop computer, a laptop computer, a hand-held microprocessing device, a tablet, a Smartphone, iPhone®, iPad®, PlayBook® and an Android® device.

25. The method of claim 19 wherein measurement data is communicated wirelessly on a peer-to-peer network to a central network manager.

26. The method of claim 19 wherein the measurement data is collected in situ from the sensor nodes or network managers.

27. The method of claim 19 which uses more than three sensor nodes.

28. The method of claim 19 which may be temporarily field deployable on one or more supply line electrical wires and then moved and reset on other supply line electrical wires without the requirement of any wire splicing for such deployment and re-deployment.

29. The method of claim 19 wherein the measurement data is transmitted wirelessly to a server, and an analysis is made to determine if a loss has occurred.

30. The method of claim 19 wherein the supply line electrical wire is a medium voltage line.
